(19) United States
(12) Patent Application Publication
(10) Pub. No.: US 2026/0164880 A1
(43) Pub. Date: Jun. 11, 2026

(54) LIGHT EMITTING APPARATUS

(71) Applicant: SEOUL VIOSYS CO., LTD., Ansan-si, Gyeonggi-do (KR)

(72) Inventor: Hongjae YOO, Ansan-si (KR)

(73) Assignee: SEOUL VIOSYS CO., LTD., Ansan-si, Gyeonggi-do (KR)

(21) Appl. No.: 19/403,317

(22) Filed: Nov. 28, 2025

Related U.S. Application Data
(60) Provisional application No. 63/728,326, filed on Dec. 5, 2024.

(51) Int. Cl. H10H 29/24; H10H 20/813

(52) U.S. Cl. CPC H10H 29/24; H10H 20/8131

(57) ABSTRACT

The present invention discloses a light emitting apparatus including a substrate and a plurality of light emitting portions disposed on one surface of the substrate, in which a CIE (x, y) coordinate value of first light emitted from one of the plurality of light emitting portions is different from a CIE (x, y) coordinate value of second light emitted from another light emitting portion.

### TECHNICAL FIELD

The present invention relates to a light emitting apparatus including a plurality of light emitting portions.

### BACKGROUND ART

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, it has been rapidly replacing a conventional light source. For example, a display apparatus using the light emitting diode may be obtained by forming structures of individually grown red R, green G, and blue B light emitting diodes (LEDs) on a final substrate.

In detail, the light emitting diode is formed by growing epitaxial layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, so that the light emitting diode is driven by being electrically connected to an external power source through the electrode pads. In this case, current may flow from the p-electrode pad through the semiconductor layers to the n-electrode pad, and light generated through recombination of electrons and holes in the active layer may be emitted.

### DISCLOSURE

### Technical Problem

The present invention aims to provide a light emitting apparatus that is configured to precisely implement a desired target chromaticity coordinate by combining light emitting devices having various chromaticity coordinates.

The present invention aims to provide a light emitting apparatus that is configured to implement a uniform and precise target color.

The present invention aims to provide a light emitting apparatus that is configured to implement a high-quality color that matches a target chromaticity coordinate, by combining and arranging light emitting devices belonging to different chromaticity coordinate regions without a need to select only light emitting devices belonging to a specific chromaticity coordinate region.

The present invention aims to provide a light emitting apparatus that is configured to have excellent color reproducibility and improve chromatic aberration.

The present invention aims to provide a light emitting apparatus that is configured to increase manufacturing yield by reducing dependence on light emitting devices in a specific chromaticity coordinate region and increase production efficiency by reducing cost, through a method of combining light emitting devices having a wide range of chromaticity coordinates.

The present invention aims to provide a light emitting apparatus with excellent color quality by minimizing chromatic aberration and increasing color uniformity through offsetting and averaging color deviations between light emitting devices.

### Technical Solution

An embodiment of the present invention discloses a light emitting apparatus including a substrate and a plurality of light emitting portions disposed on one surface of the substrate.

In an embodiment, a CIE (x, y) coordinate value of first light emitted from one of the plurality of light emitting portions may be different from a CIE (x, y) coordinate value of second light emitted from another light emitting portion.

In an embodiment, a central coordinate value of an x-coordinate of the CIE (x, y) coordinate of the first light and an x-coordinate of the CIE (x, y) coordinate of the second light may be greater than an x-coordinate of a CIE (x, y) coordinate of emitted light of the light emitting apparatus.

In an embodiment, a first light emitting portion that emits the first light and a second light emitting portion that emits the second light may be disposed adjacent to each other.

In an embodiment, the light emitting portion may be a light emitting diode.

In an embodiment, the light emitting portion may be a light emitting diode package.

In an embodiment, the light emitting portion may include a base and a plurality of light sources disposed on the base.

In an embodiment, the light source may be a light emitting diode.

In an embodiment, the light source may be a light emitting diode package.

In an embodiment, an x-coordinate value of a CIE (x, y) coordinate of third light emitted from one of the plurality of light emitting portions may be smaller than the x-coordinate value of the CIE (x, y) coordinate of the first light, and an x-coordinate value of a CIE (x, y) coordinate of fourth light emitted from one of the plurality of light emitting portions may be greater than the x-coordinate value of the CIE (x, y) coordinate of the second light.

In an embodiment, the first light emitting portion that emits the first light and the second light emitting portion that emits the second light may be disposed adjacent to each other, and a third light emitting portion that emits the third light and a fourth light emitting portion that emits the fourth light may be disposed adjacent to each other.

In an embodiment, the second light emitting portion and the third light emitting portion may be disposed adjacent to each other In an embodiment, a distance between the second light emitting portion and the third light emitting portion may be greater than a distance between the first light emitting portion and the second light emitting portion.

Another embodiment of the present invention discloses a light emitting apparatus including a substrate and a plurality of light emitting portions disposed on one surface of the substrate, in which a first peak wavelength of first light emitted from one of the plurality of light emitting portions is different from a second peak wavelength of second light emitted from another light emitting portion.

In an embodiment, a third peak wavelength of third light emitted from another one of the plurality of light emitting portions may be different from the first peak wavelength and the second peak wavelength, and a fourth peak wavelength of fourth light emitted from another one of the plurality of light emitting portions may be different from the first peak wavelength through the third peak wavelength.

In an embodiment, the third peak wavelength may be longer than the first peak wavelength, and the fourth peak wavelength may be shorter than the second peak wavelength.

In an embodiment, the third peak wavelength may be longer than the first peak wavelength, and the fourth peak wavelength may be longer than the second peak wavelength.

Another embodiment of the present invention discloses a light emitting apparatus including a substrate and a plurality of light emitting portions disposed on one surface of the substrate, in which one of the plurality of light emitting portions emits first light having a first peak wavelength, another one of the plurality of light emitting portions emits second light having a second peak wavelength, another one of the plurality of light emitting portions emits third light having a third peak wavelength, and another one of the plurality of light emitting portions emits fourth light having a fourth peak wavelength, and the third peak wavelength is longer than the first peak wavelength and shorter than the second peak wavelength.

In an embodiment, the fourth peak wavelength may be longer than the third peak wavelength and shorter than the second peak wavelength.

In an embodiment, the fourth peak wavelength may be longer than the second peak wavelength.

In an embodiment, a peak wavelength of light emitted from the light emitting apparatus may be longer than the third peak wavelength.

### Advantageous Effect

The present invention may provide a light emitting apparatus that is configured to precisely implement a desired target chromaticity coordinate by combining light emitting devices having various chromaticity coordinates.

The present invention may provide a light emitting apparatus that is configured to implement a uniform and precise target color.

The present invention may provide a light emitting apparatus that is configured to implement a high-quality color that matches a target chromaticity coordinate, by combining and arranging light emitting devices belonging to different chromaticity coordinate regions without a need to select only light emitting devices belonging to a specific chromaticity coordinate region.

The present invention may provide a light emitting apparatus that is configured to have excellent color reproducibility and improve chromatic aberration.

The present invention may provide a light emitting apparatus that is configured to increase manufacturing yield by reducing dependence on light emitting devices in a specific chromaticity coordinate region and increase production efficiency by reducing cost, through a method of combining light emitting devices having a wide range of chromaticity coordinates.

The present invention may provide a light emitting apparatus with excellent color quality by minimizing chromatic aberration and increasing color uniformity through offsetting and averaging color deviations between light emitting devices.

### BRIEF DESCRIPTION OF DRAWING

FIG. 1 is a cross-sectional view showing a light emitting apparatus according to an embodiment of the present invention.

FIG. 2 is a cross-sectional view showing a light emitting apparatus according to another embodiment of the present invention.

FIG. 3 is a drawing showing an example of a light emitting portion provided in a light emitting apparatus of the present invention.

FIG. 4 is a drawing showing another example of a light emitting portion provided in a light emitting apparatus of the present invention.

FIG. 5 is a graph showing CIE chromaticity coordinates.

FIG. 6 is a graph showing an example of an emission spectrum of light emitted from a light emitting portion provided in a light emitting apparatus of the present invention.

FIG. 7 is a graph showing another example of an emission spectrum of light emitted from a light emitting portion provided in a light emitting apparatus of the present invention.

### BRIEF DESCRIPTION OF DRAWING

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus of the present invention will be described in detail through the accompanying drawings.

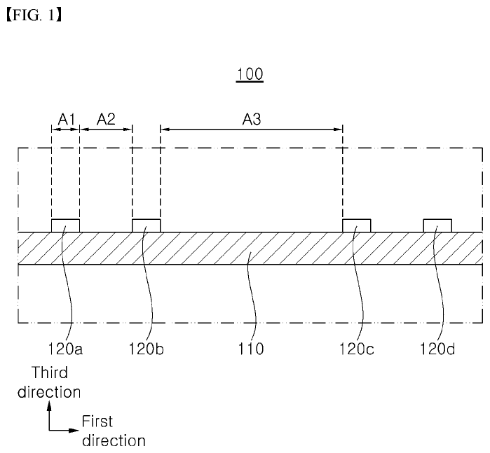

FIG. 1 illustrates a portion of a light emitting apparatus 100 according to an embodiment of the present invention, and the light emitting apparatus 100 may include a substrate 110 and a plurality of light emitting portions 120a, 120b, 120c, and 120d disposed on one surface of the substrate 110.

The substrate 110 is configured to support the plurality of light emitting portions 120a, 120b, 120c, and 120, without being limited to a specific substrate. For example, the substrate 110 may be a printed circuit board including interconnections.

The plurality of light emitting portions 120a, 120b, 120c, and 120d may be disposed on one surface of the substrate 110. The plurality of light emitting portions 120a, 120b, 120c, and 120d may be spaced apart from one another.

For example, referring to FIG. 3, the light emitting portions 120a, 120b, 120c, and 120d may include a light emitting diode device. The light emitting portions 120a, 120b, 120c, and 120d may include a semiconductor layer formed on a growth substrate 301.

Herein, the growth substrate 301 is not limited as long as it is a substrate capable of growing or disposing a semiconductor, may include, for example, a heterogeneous substrate such as a sapphire substrate, a silicon substrate, a silicon carbide substrate, or a spinel substrate, and may also include a homogeneous substrate such as a gallium nitride substrate, an aluminum nitride substrate, or others. One surface of the growth substrate 301 may be patterned to form a concave-convex or a protrusion (P). The growth substrate 301 may be removed after forming the semiconductor layer.

The semiconductor layer may include a first conductivity type semiconductor layer 302, a second conductivity type semiconductor layer 303, and active layers 304, 305, and 306 disposed between the first conductivity type semiconductor layer 302 and the second conductivity type semiconductor layer 303.

The first conductivity type semiconductor layer 302 may include a phosphide or nitride semiconductor such as (Al, Ga, In)P or (Al, Ga, In)N, and may be disposed on the growth substrate using a method such as MOCVD, MBE, HVPE, or others. For example, the first conductivity type semiconductor layer 302 is a nitride semiconductor layer doped with a first conductivity type dopant, and for example, the first conductivity type semiconductor layer 302 may be formed of an InₓAl_{y}Ga_{(1-x-y)}N (0≤x≤0, 0≤y≤1, 0≤x+y≤1) layer doped with Si as the first conductivity type dopant.

In addition, the first conductivity type semiconductor layer 302 may be doped as n-type by including one or more impurities such as Si, C, Ge, Sn, Te, Pb, or others. However, the inventive concepts are not limited thereto, the first conductivity type semiconductor layer 302 may be doped with an opposite conductivity type, including a p-type dopant. A doping concentration of the first conductivity type dopant may be 5×10¹⁷ atoms/cm³ to 5×10¹⁹ atoms/cm³.

The first conductivity type semiconductor layer 302 may be configured as a single layer, or may include a plurality of layers. The first conductivity type semiconductor layer 302 may further include a nucleation layer and a buffer layer. In addition, the first conductivity type semiconductor layer 302 may further include a superlattice layer. The superlattice layer may be formed over the first conductivity type semiconductor layer 302. In addition, the first conductivity type semiconductor layer 302 may further include a contact layer, a modulation doping layer, an electron injection layer, or others.

The second conductivity type semiconductor layer 303 may include a phosphide or nitride semiconductor such as (Al, Ga, In)P or (Al, Ga, In)N, and may be grown using a technique such as MOCVD, MBE, HVPE, or others. The second conductivity type semiconductor layer 303 may be doped with a second conductivity type dopant which is a conductivity type opposite to that of the first conductivity type semiconductor layer 302. For example, the second conductivity type semiconductor layer 303 may be doped as a p-type by including an impurity such as Mg. The second conductivity type semiconductor layer 303 may be formed of, for example, InₓAl_{y}Ga_{(1-x-y)}N (0≤x≤1, 0≤y≤1, 0≤x+y≤1).

In addition, the second conductivity type semiconductor layer 303 may be configured as a single layer having a composition such as p-InₓAl_{y}Ga_{(1-x-y)}N (0≤x≤1, 0≤y≤1, 0≤x+y≤1) or may include a plurality of layers. In addition, the second conductivity type semiconductor layer 303 may further include a layer including Al therein. In addition, the second conductivity type semiconductor layer 303 may further include a superlattice layer. In addition, the second conductivity type semiconductor layer 303 may further include a second conductivity type contact layer.

The active layers 304, 305, and 306 may be light emitting layers disposed between the first conductivity type semiconductor layer 302 and the second conductivity type semiconductor layer 303. The active layers 304, 305, and 306 may be disposed on one surface of the first conductivity type semiconductor layer 302.

The active layers 304, 305, and 306 may include a phosphide or nitride semiconductor such as (Al, Ga, In)Por (Al, Ga, In)N, and may be grown on one surface of the first conductivity type semiconductor layer 302 using a technique such as MOCVD, MBE, HVPE, or others.

The active layers 304, 305, and 306 may include a quantum well structure (QW) including at least two barrier layers 132 and at least one well layer 134. Alternatively, the active layers 304, 305, and 306 may include a multi quantum well structure (MQW) of barrier layers and well layers alternately disposed. The multi quantum well structure (MQW) may include a plurality of barrier layers and well layers alternately disposed. Adjacent barrier layers and well layers may form a pair. The active layers 304, 305, and 306 may include a plurality of pairs.

The well layer and barrier layer may be formed of, for example, a semiconductor material having a composition formula of InₓAl_{y}Ga_{(1-x-y)}N (0≤x≤1, 0≤y≤1, 0≤x+y≤1). For example, they may include at least one of InGaN/GaN, GaN/AlGaN, AlGaN/AlGaN, InGaN/AlGaN or InGaN/InGaN.

A wavelength of light emitted from the active layers 304, 305, and 306 may be adjusted by controlling a composition ratio of materials forming the well layer. A composition and a thickness of the well layer may determine the wavelength of light generated. In particular, by adjusting the composition of the well layer, the active layers 304, 305, and 306 that generate ultraviolet light, blue light, red light, or green light may be provided.

The first conductivity type semiconductor layer 302, the active layers 304, 305, and 306, and the second conductivity type semiconductor layer 303 may be a light emitting structure that emits light having a preset peak wavelength as a semiconductor stack. That is, the semiconductor stack may emit light of blue, green, red, or others.

In detail, a semiconductor stack emitting blue light has a dominant wavelength within a blue wavelength range, and in detail, may have the dominant wavelength between 440 nm and 480 nm. A semiconductor stack emitting green light has a dominant wavelength within a green wavelength range, and in detail, may have the dominant wavelength between 480 nm and 580 nm. A peak wavelength of green light may be shorter than the dominant wavelength. A semiconductor stack emitting red light has a dominant wavelength within a red wavelength range, and in detail, may have the dominant wavelength between 600 nm and 650 nm. A peak wavelength of red light may be a wavelength longer than the dominant wavelength.

The active layers 304, 305, and 306 may be provided in a plurality of numbers. FIG. 3 exemplarily illustrates that a semiconductor layer includes three first through third active layers 304, 305, and 306, but a number of active layers 304, 305, and 306 is not limited thereto.

The dominant wavelengths of light emitted from each of the active layers 304, 305, and 306 may be different from one another. For example, the first active layer 304 may emit green light, the second active layer 305 may emit blue light, and the third active layer 306 may emit red light. Accordingly, light emitted from the first through third active layers 304, 305, and 306 may be mixed to emit white light.

The light emitting portions 120a, 120b, 120c, and 120d may include a mesa structure in which a portion of a semiconductor layer is etched. A portion of an upper surface of the first conductivity type semiconductor layer 302 may be exposed around the mesa.

The light emitting portions 120a, 120b, 120c, and 120d may include a first contact electrode 307 in contact with the first conductivity type semiconductor layer 302 and a second contact electrode 308 in contact with the second conductivity type semiconductor layer 303. The light emitting portions 120a, 120b, 120c, and 120d may be disposed on one surface of the substrate 110 and may be electrically connected to the substrate 110 through the first contact electrode 307 and the second contact electrode 308.

The structure of the light emitting portions 120a, 120b, 120c, and 120d of FIG. 3 is merely exemplary, and the present invention is not limited thereto.

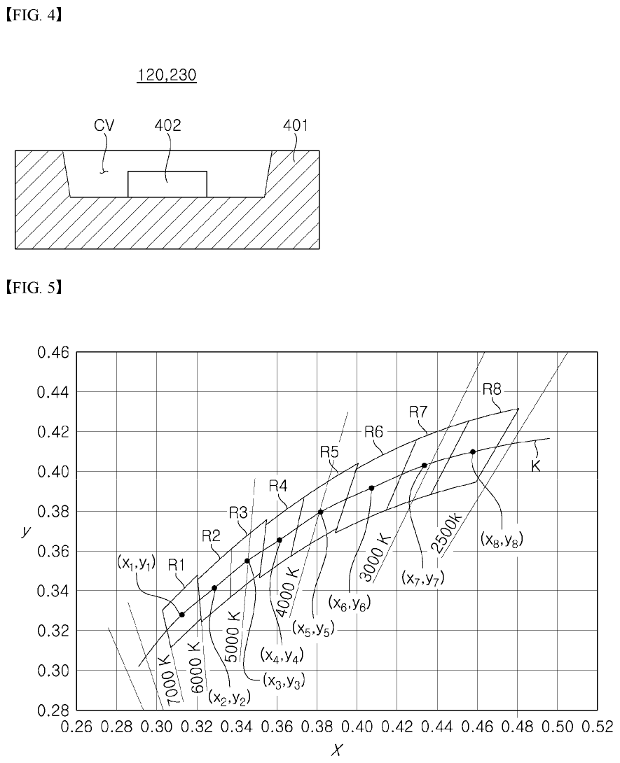

As another example, referring to FIG. 4, the light emitting portions 120a, 120b, 120c, and 120d may be a light emitting diode package.

The light emitting diode package may include a frame 401 and a light emitting diode device 402 mounted within the frame 401.

The frame 401 may form a body of the light emitting diode package, and may physically support the light emitting diode device 402 and protect it from an external environment. The frame 401 may be formed of various insulating and heat-resistant materials such as thermosetting resin, thermoplastic resin, ceramic, metallic materials, or others.

A concavely formed cavity CV may be provided in an upper portion of the frame 401. The cavity CV may form a space in which the light emitting diode device 402 is disposed. An inner surface of the cavity CV may be formed to be inclined, which may form a reflection surface so as to efficiently reflect light generated from the light emitting diode device 402 to the outside to increase light extraction efficiency. The reflection surface may be coated with a high-reflectivity material such as silver (Ag).

The light emitting diode device 402 functioning as a light source may be mounted on a bottom surface of the cavity CV. The light emitting diode device 402 may emit light having a specific peak wavelength when current is applied (e.g., visible light or ultraviolet light). The light emitting diode device 402 may be electrically and physically connected to a lead frame (not shown in the drawings) within the frame 401 through a bonding technique such as die bonding or flip-chip bonding.

To realize light of a specific chromaticity coordinate, an interior of the cavity CV may be filled with an encapsulant including a wavelength conversion material. For example, in a case that the light emitting diode device 402 emits blue light, a yellow phosphor or green and red phosphors included in the encapsulant may absorb a portion of blue light and convert it into light of a longer wavelength (yellow, green, or red light). Converted light, and remaining blue light that does not pass through the phosphors may be mixed to ultimately emit white light or light with a specific correlated color temperature to the outside of the package.

By precisely adjusting a type, a concentration, and a combination of the phosphors used, each of the light emitting portion 120a, 120b, 120c, and 120d may emit light having a specific CIE chromaticity coordinate (x, y) value.

Referring back to FIG. 1, a CIE (x, y) coordinate value of first light emitted from one of the plurality of light emitting portions 120a, 120b, 120c, and 120d may be different from a CIE (x, y) coordinate value of second light emitted from another light emitting portion 120a, 120b, 120c, or 120d. For example, the CIE (x, y) coordinate value of first light may be smaller than the CIE (x, y) coordinate value of second light.

In detail, one of the plurality of light emitting portions 120a, 120b, 120c, and 120d may be a first light emitting portion 120a that emits first light, and the other one may be a second light emitting portion 120b that emits second light.

The first light emitting portion 120a that emits the first light and the second light emitting portion 120b that emits the second light may be disposed adjacent to each other.

A width Al of the first light emitting portion 120a or the second light emitting portion 120b may be smaller than a distance A2 between the first light emitting portion 120a and the second light emitting portion 120b.

FIG. 5 is a graph showing a CIE 1931 chromaticity diagram illustrating a chromaticity coordinate distribution and combination of the light emitting portions 120a, 120b, 120c, and 120d of the present invention. A transverse axis of FIG. 5 represents an x-chromaticity coordinate, a vertical axis represents a y-chromaticity coordinate, and a curve k crossing a center represents a planckian locus, which represents a chromaticity coordinate of light emitted by an ideal black-body depending on a temperature.

The planckian locus may be used as a standard reference for white light. Lines marked 7000K, 6000K, . . . , 2500K may be isothermal lines connecting points with a same correlated color temperature (CCT).

In a light emitting diode (LED) manufacturing process, a chromaticity coordinate of each produced device may not be exactly matched with a target point due to minute differences in materials and process conditions but may be distributed within a specific range. Therefore, a sorting process (binning) may be required to classify the produced devices into several groups according to the chromaticity coordinates thereof.

Each region from R1 through R8 shown in FIG. 5 may represent an individual chromaticity coordinate bin defined by this binning process. For example, the R1 may represent a group of light emitting devices centered around a correlated color temperature of approximately 7000K, the R 4 a group centered around 4000K, and the R7 a group centered around 2700K. Points within each of the regions R1 through R8 (e.g., (x₁, y₁), (x₂, y₂), . . . , (x₈, y₈)) may be a center chromaticity coordinate of a corresponding bin.

The CIE (x, y) chromaticity coordinate of first light emitted from the first light emitting portion 120a and the CIE (x, y) chromaticity coordinate of second light emitted from the second light emitting portion 120b may be positioned in different regions on the CIE 1931 chromaticity diagram. For example, the CIE (x, y) chromaticity coordinate of the first light may be positioned in the R3 region, and the CIE (x, y) chromaticity coordinate of the second light may be positioned in the R7 region.

Mixed light in which the first light and the second light are mixed may be emitted as emitted light of the light emitting apparatus 100. Accordingly, a CIE (x, y) chromaticity coordinate of the emitted light may have a value different from the CIE (x, y) chromaticity coordinate of first light and the CIE (x, y) chromaticity coordinate of second light.

A central coordinate value of an x-coordinate of the CIE (x, y) coordinate of the first light and an x-coordinate of the CIE (x, y) coordinate of the second light may be greater than an x-coordinate of the CIE (x, y) coordinate of the emitted light of the light emitting apparatus. Herein, the central coordinate value of the x-coordinate may be an average value of an x-value of the CIE (x, y) coordinate of first light and an x-value of the CIE (x, y) coordinate of second light.

Alternatively, a central coordinate value of a y-coordinate of the CIE (x, y) coordinate of the first light and a y-coordinate of the CIE (x, y) coordinate of the second light may be greater than a x-coordinate of the CIE (x, y) coordinate of the emitted light of the light emitting apparatus. Herein, the central coordinate value of the y-coordinate may be an average value of a y-value of the CIE (x, y) coordinate of first light and a y-value of the CIE (x, y) coordinate of second light.

Alternatively, a difference between the x-coordinate of the CIE (x, y) coordinate of the second light and the x-coordinate of the CIE (x, y) coordinate of the first light may be greater than a difference between the y-coordinate of the CIE (x, y) coordinate of the second light and the y-coordinate of the CIE (x, y) coordinate of the first light.

Alternatively, a difference between the x-coordinate of the CIE (x, y) coordinate of the emitted light of the light emitting apparatus and the x-coordinate of the CIE (x, y) coordinate of the first light may be smaller than a difference between the x-coordinate of the CIE (x, y) coordinate of the second light and the x-coordinate of the CIE (x, y) coordinate of the emitted light of the light emitting apparatus 100.

Alternatively, a difference between the y-coordinate of the CIE (x, y) coordinate of the emitted light of the light emitting apparatus and the y-coordinate of the CIE (x, y) coordinate of the first light may be smaller than a difference between the y-coordinate of the CIE (x, y) coordinate of the emitted light of the light emitting apparatus and the y-coordinate of the CIE (x, y) coordinate of the second light.

Alternatively, a difference between the y-coordinate and the x-coordinate of the CIE (x, y) coordinate of the first light may be smaller than a difference between the y-coordinate and the x-coordinate of the CIE (x, y) coordinate of the second light.

In detail, when the CIE (x, y) chromaticity coordinate of first light is (x₃, y₃) in the region R3 and the CIE (x, y) chromaticity coordinate of second light is (x₇, y₇) in the region R7, the CIE (x, y) chromaticity coordinate of emitted light of the light emitting apparatus 100 may be positioned in the region R5.

When the CIE (x, y) chromaticity coordinate of the emitted light is (x₅, y₅), a central coordinate value (x₃+x₇)/2 of x₃ and x₇ may have a value greater than x₅. (x₃+x₇)/2 >x₅)

Alternatively, a central coordinate value (y₃+y₇)/₂ of y₃ and y₇ may have a value greater than y₅. ((y₃+y₇)/2 >y₅)

Alternatively, x₇−x₃ may have a value greater than y₇−y₃. (x₇−x₃>y₇−y₃)

Alternatively, x₅−x₃ may have a value smaller than x₇−x₅. (x₅−x₃<x₇−x₅)

Alternatively, y₅−y₃ may have a value smaller than y₇−y₅. (y₅−y₃<y₇−y₅)

Alternatively, y₃−x₃ may have a value smaller than y₇−x₇. (y₃−x₃<y₇−x₇)

That is, by disposing the plurality of light emitting portions 120a, 120b, 120c, and 120d designed to have different chromaticity coordinates (e.g., (x₃, y₃) and (x₇, y₇)) on one substrate 110, CIE chromaticity coordinates of an entire light emitting apparatus 100 may be prevented from deviating from an intended region, thereby controlling color uniformity and improving yield.

Exemplarily, the first light emitting portion 120a may have a CIE chromaticity coordinate (Xa, Ya) value within a range of 0.205<xₐ<0.495, 0.190<yₐ<0.450. The second light emitting portion 120b may have a CIE chromaticity coordinate (x_{b}, y_{b}) value within a range of 0.205<x_{b}<0.495, 0.190<y_{b}<0.450.

The xₐ and the x_{b} have different values, and an absolute value of xₐ−x_{b} may be greater than 0 and smaller than 0.290. In this case, an x-coordinate value of the CIE chromaticity coordinate of emitted light emitted from the light emitting device 100 may have a value between the xₐ and the x_{b}.

By simultaneously turning on the first and second light emitting portions 120a and 120b having the different chromaticity coordinate CIE x-coordinate values, it is possible to prevent the CIE x-coordinate value of light emitted from the light emitting apparatus 100 from deviating from the range of 0.205<x<0.495.

Similarly, the yₐ and the y_{b} have different values, and an absolute value of yₐ−y_{b} may be greater than 0 and smaller than 0.260. In this case, a y-coordinate value of the CIE chromaticity coordinate of emitted light emitted from the light emitting apparatus 100 may have a value between the yₐ and the y_{b}.

By simultaneously turning on the first and second light emitting portions 120a and 120b having the different chromaticity coordinate CIE y-coordinate values, it is possible to prevent the CIE y-coordinate value of light emitted from the light emitting apparatus 100 from deviating from a range of 0.109<y<0.450.

The light emitting apparatus 100 may further include a third light emitting portion 120c that emits third light and a fourth light emitting portion 120d that emits fourth light. A CIE (x, y) coordinate value of the third light may be different from a CIE (x, y) coordinate value of the fourth light.

An x-coordinate value of the CIE (x, y) coordinate of the third light may be smaller than the x-value of the CIE (x, y) coordinate of the first light. An x-coordinate value of the CIE (x, y) coordinate of the fourth light may be greater than the x-value of the CIE (x, y) coordinate of the second light. A y-coordinate value of the CIE (x, y) coordinate of the third light may be smaller than the y-value of the CIE (x, y) coordinate of the first light. A y-coordinate value of the CIE (x, y) coordinate of the fourth light may be greater than the y-value of the CIE (x, y) coordinate of the second light. For example, the CIE (x, y) coordinate of the third light may be positioned in the region R2, and the CIE (x, y) coordinate of the fourth light may be positioned in the region R8.

Alternatively, the x-coordinate value of the CIE (x, y) coordinate of third light may be greater than the x-value of the CIE (x, y) coordinate of the first light, and smaller than the x-value of the CIE (x, y) coordinate of the second light. The x-coordinate value of the CIE (x, y) coordinate of the fourth light may also be greater than the x-value of the CIE (x, y) coordinate of the first light, and smaller than the x-value of the CIE (x, y) coordinate of the second light. The y-coordinate value of the CIE (x, y) coordinate of the third light may be greater than the y-value of the CIE (x, y) coordinate of the first light, and smaller than the y-value of the CIE (x, y) coordinate of the second light. The y-coordinate value of the CIE (x, y) coordinate of the fourth light may also be greater than the y-value of the CIE (x, y) coordinate of the first light, and smaller than the y-value of the CIE (x, y) coordinate of second light. For example, the CIE (x, y) coordinate of the third light may be positioned in the region R4, and the CIE (x, y) coordinate of the fourth light may be positioned in the region R6.

Alternatively, the x-coordinate value of the CIE (x, y) coordinate of third light may be greater than the x-value of the CIE (x, y) coordinate of the first light, and smaller than the x-value of the CIE (x, y) coordinate of the second light. The x-coordinate value of the CIE (x, y) coordinate of the fourth light may be greater than the x-value of the CIE (x, y) coordinate of the second light. The y-coordinate value of the CIE (x, y) coordinate of the third light may be greater than the y-value of the CIE (x, y) coordinate of the first light, and smaller than the y-value of the CIE (x, y) coordinate of second light. The y-coordinate value of the CIE (x, y) coordinate of the fourth light may be greater than the y-value of the CIE (x, y) coordinate of second light. For example, the CIE (x, y) coordinate of the third light may be positioned in the region R4, and the CIE (x, y) coordinate of the fourth light may be positioned in the region R8. Accordingly, a CIE (x, y) coordinate value of mixed light in which first light and second light are mixed may be formed close to the CIE (x, y) coordinate value of third light, and a CIE (x, y) coordinate value of mixed light in which third light and fourth light are mixed may be formed close to the CIE (x, y) coordinate value of second light, thereby reducing a chromatic aberration of the light emitting apparatus 100.

The CIE (x, y) coordinate of the mixed light in which the third light and the fourth light are mixed may be different from the CIE (x, y) coordinates of the third light and the fourth light. For example, the CIE (x, y) coordinate of the mixed light may be positioned in the region R5.

The third light emitting portion 120c and the fourth light emitting portion 120d may be disposed adjacent to each other. In addition, the second light emitting portion 120b and the third light emitting portion 120c may be disposed adjacent to each other.

A distance A3 between the second light emitting portion 120b and the third light emitting portion 120c may be greater than the distance A2 between the first light emitting portion 120a and the second light emitting portion 120b.

A wavelength deviation of dominant wavelengths between mixed light of first light and second light emitted from the first light emitting portion 120a and the second light emitting portion 120b and mixed light of third light and fourth light emitted from the third light emitting portion 120c and the fourth light emitting portion 120d may be 20 nm or less.

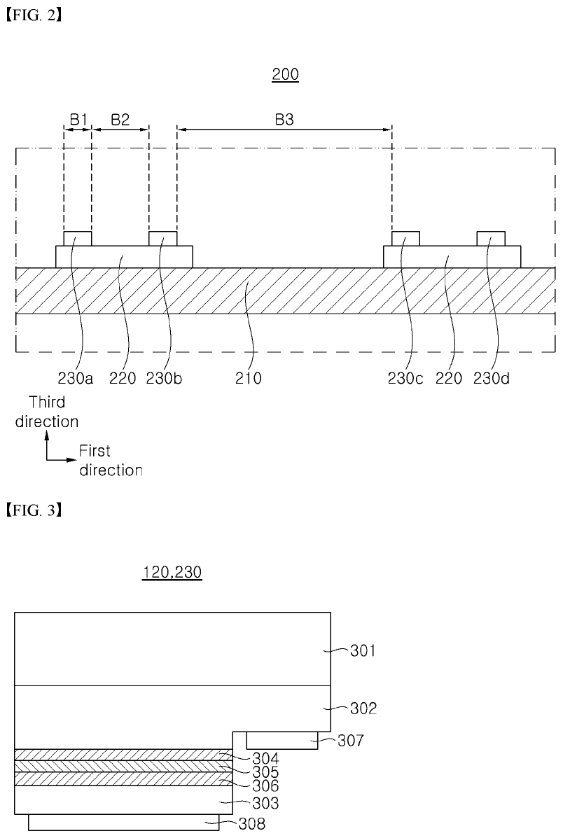

FIG. 2 illustrates a portion of a light emitting apparatus 200 according to another embodiment of the present invention, and the light emitting apparatus 200 may include a substrate 210 and a plurality of light emitting portions disposed on one surface of the substrate 210.

The light emitting portion may include a base 220 and a plurality of light sources 230a, 230b, 230c, and 230d disposed on the base 220.

The base 220 is configured to support the plurality of light sources 230a, 230b, 230c, and 230d on one surface thereof and various configurations are possible.

The light sources 230a, 230b, 230c, and 230d may be light emitting diodes. Alternatively, the light sources 230a, 230b, 230c, and 230d may be a light emitting diode package. For example, the light sources 230a, 230b, 230c, and 230d may be configured to be identical or similar to the light emitting portions 120a, 120b, 120c, and 120d of the light emitting apparatus 100 of FIG. 1.

One of the plurality of light emitting portions may include a first light source 230a and a second light source 230b disposed on the base 220. Another one of the plurality of light emitting portions may include a third light source 230c and a fourth light source 230d disposed on the base 220.

The first through fourth light sources 230a, 230b, 230c, and 230d may be configured to be identical or similar to the first through fourth light emitting portions 120a, 120b, 120c, and 120d of the light emitting apparatus 100 of FIG. 1. Accordingly, a difference in CIE (x, y) coordinate values of light emitted from each of the light emitting portions may be reduced, thereby increasing a uniformity of chromaticity coordinates between the light emitting portions. In addition, it is possible to increase a probability that a CIE (x, y) coordinate value of light emitted from the light emitting apparatus 200 is disposed in a region of Ansi step.

In another embodiment of the present invention, referring again to FIG. 1, a first peak wavelength W1 of first light emitted from one of the plurality of light emitting portions 120a, 120b, 120c, and 120d may be different from a second peak wavelength W2 of second light emitted from another light emitting portion 120a, 120b, 120c, or 120d. In addition, a third peak wavelength W3 of third light emitted from another one of the plurality of light emitting portions 120a, 120b, 120c, and 120d may be different from the first peak wavelength W1 and the second peak wavelength W2. In addition, a fourth peak wavelength W4 of fourth light emitted from another one of the plurality of light emitting portions 120a, 120b, 120c, and 120d may be different from the first peak wavelength through the third peak wavelength W1, W2, and W3.

In the light emitting apparatuses 100 and 200, the first light emitting portion 120a or the first light source 230a may emit first light having the first peak wavelength W1, the second light emitting portion 120b or the second light source 230b may emit second light having the second peak wavelength W2, the third light emitting portion 120c or the third light source 230c may emit third light having the third peak wavelength W3, and the fourth light emitting portion 120d or the fourth light source 230d may emit fourth light having the fourth peak wavelength W4.

For example, dominant wavelengths of first and second lights emitted from the first and second light emitting portions 120a and 120b may be different from each other. In this case, a wavelength deviation of the dominant wavelengths of first and second lights may be 20 nm or more. As another example, the first and second light emitting portions 120a and 120b may emit white light, and a wavelength deviation of dominant wavelengths thereof may be 20 nm or less.

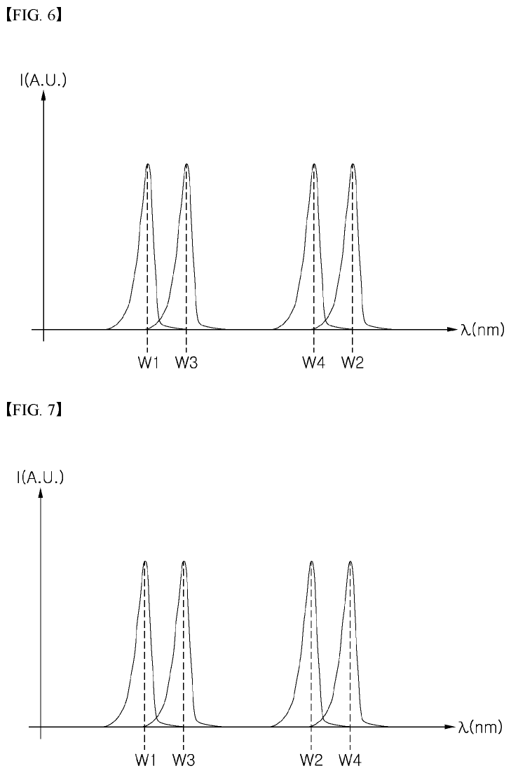

Referring to FIG. 6, the third peak wavelength W3 may be longer than the first peak wavelength W1 and shorter than the second peak wavelength W2. The fourth peak wavelength W4 may also be longer than the first peak wavelength W1 and shorter than the second peak wavelength W2. In addition, the fourth peak wavelength W4 may be longer than the third peak wavelength W3. Accordingly, a difference between an average value of the peak wavelengths W1 and W2 of first and second lights and an average value of the peak wavelengths W3 and W4 of third and fourth lights may be reduced, thereby reducing an average wavelength deviation between mixed light of first and second lights and mixed light of third and fourth lights.

In contrast, the third peak wavelength W3 may be shorter than the first peak wavelength W1. The fourth peak wavelength W4 may be longer than the second peak wavelength W2. Accordingly, the difference between the average value of the peak wavelengths W1 and W2 of first and second lights and the average value of the peak wavelengths W3 and W4 of third and fourth lights may be reduced, thereby reducing the average wavelength deviation between mixed light of first and second lights and mixed light of third and fourth lights.

Mixed light in which the first through fourth lights are mixed may be emitted from the light emitting apparatuses 100 and 200, and a peak wavelength of a corresponding emitted light may be longer than the third peak wavelength W3.

As another example, referring to FIG. 7, the third peak wavelength W3 may be longer than the first peak wavelength W1, and shorter than the second peak wavelength W2. The fourth peak wavelength W4 may be longer than the second peak wavelength W2. Therefore, the difference between the average values of the peak wavelengths W1 and W2 of first and second lights and average values of the peak wavelengths W3 and W4 of third and fourth lights may be reduced, thereby reducing the average wavelength deviation between mixed light of first and second lights and mixed light of third and fourth lights.

Alternatively, the third peak wavelength W3 may be shorter than the first peak wavelength W1. The fourth peak wavelength W4 may be longer than the first peak wavelength W1 and shorter than the second peak wavelength W2. Therefore, the difference between the average value of the peak wavelengths W1 and W2 of first and second lights and the average value of the peak wavelengths W3 and W4 of third and fourth lights may be reduced, thereby reducing the average wavelength deviation between mixed light of first and second lights and mixed light of third and fourth lights.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200: Light emitting apparatus
110, 210: Substrate
120a, 120b, 120c, 120d: Light emitting portion
220: Base
230a, 230b, 230c, 230d: Light source

1. A light emitting apparatus, comprising:
a substrate; and
a plurality of light emitting portions disposed on a first surface of the substrate,
wherein a CIE (x, y) coordinate value of a first light emitted from a first light emitting portion of the plurality of light emitting portions is different from a CIE (x, y) coordinate value of a second light emitted from a second light emitting portion of the plurality of light emitting portions.

2. The light emitting apparatus of claim 1,
wherein a central coordinate value of an x-coordinate of the CIE (x, y) coordinate of the first light and an x-coordinate of the CIE (x, y) coordinate of the second light is greater than an x-coordinate of a CIE (x, y) coordinate of emitted light of the light emitting apparatus.

3. The light emitting apparatus of claim 1,
wherein the first light emitting portion that emits the first light and the second light emitting portion that emits the second light are disposed adjacent to each other.

4. The light emitting apparatus of claim 1,
wherein each of the plurality of light emitting portions is a light emitting diode.

5. The light emitting apparatus of claim 1,
wherein each of the plurality of light emitting portions a light emitting diode package.

6. The light emitting apparatus of claim 1,
wherein each of the plurality of light emitting portions includes a base and a plurality of light sources disposed on the base.

7. The light emitting apparatus of claim 6,
wherein each of the plurality of light sources is a light emitting diode.

8. The light emitting apparatus of claim 6, wherein each of the plurality of light sources is a light emitting diode package.

9. The light emitting apparatus of claim 1, wherein:
an x-coordinate value of a CIE (x, y) coordinate of a third light emitted from a third light emitting portion of the plurality of light emitting portions is smaller than an x-coordinate value of the CIE (x, y) coordinate of the first light, and
an x-coordinate value of a CIE (x, y) coordinate of a fourth light emitted from a fourth light emitting portion of the plurality of light emitting portions is greater than an x-value of the CIE (x, y) coordinate of the second light.

10. The light emitting apparatus of claim 9, wherein:
the first light emitting portion that emits the first light and the second light emitting portion that emits the second light are disposed adjacent to each other, and the third light emitting portion that emits the third light and the fourth light emitting portion that emits the fourth light are disposed adjacent to each other.

11. The light emitting apparatus of claim 10,
wherein the second light emitting portion and the third light emitting portion are disposed adjacent to each other.

12. The light emitting apparatus of claim 11,
wherein a distance between the second light emitting portion and the third light emitting portion is greater than a distance between the first light emitting portion and the second light emitting portion.

13. A light emitting apparatus, comprising:
a substrate; and
a plurality of light emitting portions disposed on a first surface of the substrate,
wherein a first peak wavelength of a first light emitted from a first light emitting portion of the plurality of light emitting portions is different from a second peak wavelength of a second light emitted from a second light emitting portion of the plurality of light emitting portions.

14. The light emitting apparatus of claim 13, wherein:
a third peak wavelength of a third light emitted from a third light emitting portion of the plurality of light emitting portions is different from the first peak wavelength and the second peak wavelength, and
a fourth peak wavelength of a fourth light emitted from a fourth light emitting portion of the plurality of light emitting portions is different from the first peak wavelength, the second peak wavelength, and the third peak wavelength.

15. The light emitting apparatus of claim 14, wherein:
the third peak wavelength is longer than the first peak wavelength, and the fourth peak wavelength is shorter than the second peak wavelength.

16. The light emitting apparatus of claim 14, wherein:
the third peak wavelength is longer than the first peak wavelength, and
the fourth peak wavelength is longer than the second peak wavelength.

17. A light emitting apparatus, comprising:
a substrate; and
a plurality of light emitting portions disposed on a first surface of the substrate, wherein:
a first light emitting portion of the plurality of light emitting portions emits a first light having a first peak wavelength,
a second light emitting portion of the plurality of light emitting portions emits a second light having a second peak wavelength,
a third light emitting portion of the plurality of light emitting portions emits a third light having a third peak wavelength,
a fourth light emitting portion of the plurality of light emitting portions emits a fourth light having a fourth peak wavelength, and
the third peak wavelength is longer than the first peak wavelength and shorter than the second peak wavelength.

18. The light emitting apparatus of claim 17,
wherein the fourth peak wavelength is longer than the third peak wavelength and shorter than the second peak wavelength.

19. The light emitting apparatus of claim 17,
wherein the fourth peak wavelength is longer than the second peak wavelength.

20. The light emitting apparatus of claim 17,
wherein a peak wavelength of light emitted from the light emitting apparatus is longer than the third peak wavelength.
